(19) United States
(12) Patent Application Publication
(10) Pub. No.: US 2011/0240359 A1
(43) Pub. Date: Oct. 6, 2011

(54) VEHICULAR DRIVE BY WIRE SYSTEM SHIELDING AND GROUNDING

(76) Inventors: GERALD MILTON WINTERS, JR., Hackensack, NJ (US); Roy Franklin Wilt, Cape Coral, FL (US)

(21) Appl. No.: 13/033,342

(22) Filed: Feb. 23, 2011

Related U.S. Application Data
(60) Provisional application No. 61/320,419, filed on Apr. 2, 2010.

(51) Int. Cl. H05K 9/00

(52) U.S. Cl. 174/350

(57) ABSTRACT

A shielding system for protecting a drive by wire system includes a conductive computer shield that may be tied electrically to chassis ground for encasing computers within the drive by wire system, and a conductive bus shield that may also be tied electrically to chassis ground for encasing busses that carry signals between the computers within the drive by wire system.

### CROSS-REFERENCE TO RELATED APPLICATIONS

This application claims the benefit of priority to U.S. provisional patent application No. 61/320,419 filed Apr. 2, 2010, and incorporated herein by reference.

### BACKGROUND OF THE INVENTION

The present invention generally relates to shielding and grounding, and more particularly relates to shielding and grounding of computer-controlled vehicular drive by wire systems that prevent interference from radio and electromagnetic interference.

### SUMMARY OF THE INVENTION

In one aspect of the present invention, a shielding system for protecting a drive by wire system may comprise a conductive computer shield tied electrically to chassis ground for encasing computers within a drive by wire system; and a conductive bus shield tied electrically to chassis ground for encasing busses that carry signals between the computers within the drive by wire system.

In another aspect of the present invention, a method for shielding a drive by wire system may comprise enclosing computers within the drive by wire system with a conductive computer shield; enclosing busses that carry signals between the computers within the drive by wire system with a conductive bus shield; tying the conductive connector shield to ground; and tying the conductive bus shield to ground.

These and other features, aspects and advantages of the present invention will become better understood with reference to the following drawings, description and claims.

### BRIEF DESCRIPTION OF THE DRAWINGS

FIG. 1 shows a schematic of a vehicular drive by wire system enclosed by conductive shields tied electrically to chassis ground in accordance with an embodiment of the present invention;

FIG. 2 shows a perspective view of a connector case in accordance with an embodiment of the present invention;

FIG. 3 shows an exploded perspective view of the connector case of FIG. 2;

FIG. 4 shows a cross-sectional view of an electrical bus taken on line 4-4 of FIG. 3;

FIG. 5 shows an exploded perspective view of an actuator case in accordance with an embodiment of the present invention; and

FIG. 6 shows a perspective view of a computer case in accordance with an embodiment of the present invention.

### DETAILED DESCRIPTION OF THE INVENTION

The following detailed description is of the best currently contemplated modes of carrying out exemplary embodiments of the invention. The description is not to be taken in a limiting sense, but is made merely for the purpose of illustrating the general principles of the invention, since the scope of the invention is best defined by the appended claims.

Various inventive features are described below that can each be used independently of one another or in combination with other features.

Broadly, embodiments of the present invention generally provide shielding and grounding of computer-controlled vehicular drive by wire systems to prevent radio, electromagnetic, and other forms of interference from disrupting proper operation of the drive by wire system.

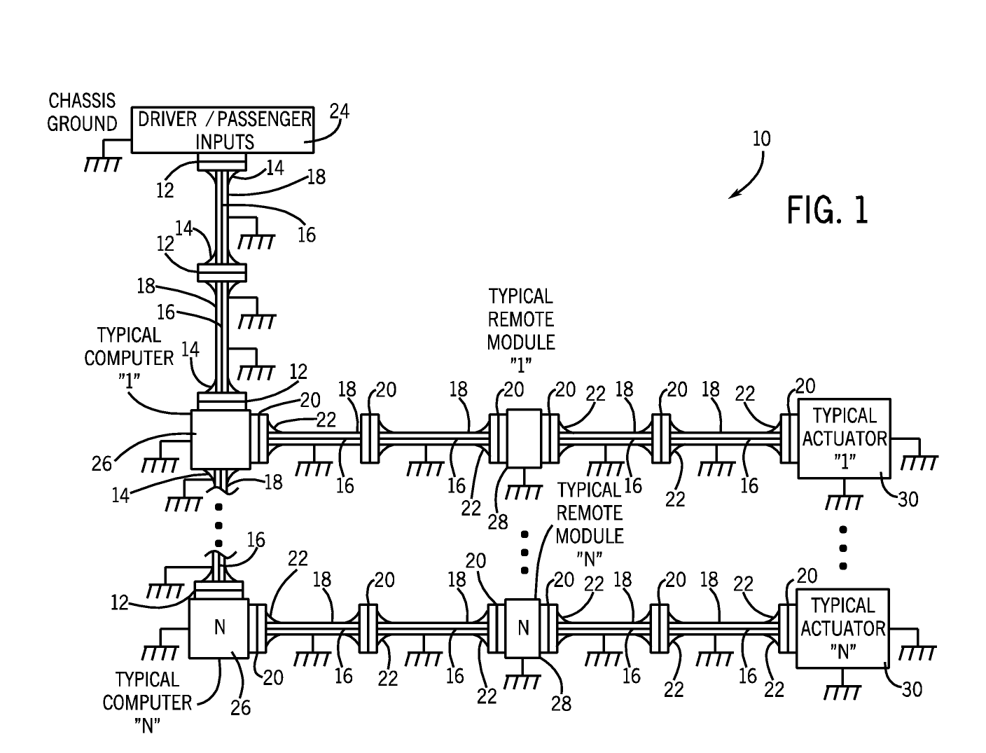

Referring now to FIG. 1, a computer-controlled vehicular drive by wire system 10 may replace traditional mechanical linkages with an electronic control system where driver/passenger inputs 24 may be communicated to electromechanical actuators 30 via computer busses 16 that carry signals between the inputs 24 and the actuators 30. Computers 26 and remote modules 28 may also be situated between the inputs 24 and the actuators 30. The computers 26 may, for example, interpret signals sent from the inputs 24 to output control signals through the busses 16 to control the actuators 30.

The driver/passenger inputs 24 may be mated to computer busses 16 via mated connectors 12 to communicate with computers 26 that may also be mated to the computer busses 16 via mated connectors 12. The computers 26 may also be mated to computer busses 16 via mated connectors/bulkheads 20 to communicate with remote modules 28 that also may be mated to the computer busses 16 via mated connectors/bulkheads 20. The remote modules 28may also be mated to computer busses 16 via mated connectors/bulkheads 20 to communicate with actuators 30 that may also be mated to the computer busses 16 via mated connectors/bulkheads 20.

To help prevent outside interference, such as interference from radio or electromagnetic signals, the drive by wire system including the driver/passenger inputs 24, the computers 26, the remote modules 28, the actuators 30, the mated connectors 12, the mated connectors/bulkheads 20 and the computer busses 16 may be shielded by conductive materials 14 and 18 that may be completely enclosed electrically and that may be grounded electrically to chassis ground, such as the body of the vehicle, at multiple points.

The shielding of the drive by wire system may help to eliminate any penetration of external radio frequencies and electromagnetic interference emanating from outside sources, thereby allowing signals and computer commands to be properly recognized and interpreted within the drive by wire system. Furthermore, by tying the shielding to chassis ground, the interfering signals may be shunted to chassis ground.

For example, the driver/passenger inputs 24, the computers 26, the remote modules 28, the actuators 30 may each be completely enclosed by a conductive shield 32 that is tied electrically to chassis ground. The mated connectors 12 may be completely enclosed by conductive connector shields 14 that are tied electrically to the chassis ground. The mated connectors/bulkhead 20 may be completely enclosed by conductive connector and bulkhead shields 22 that are tied electrically to chassis ground. The computer busses 16 may be completely enclosed by conductive bus shields 18 that are tied electrically to chassis ground.

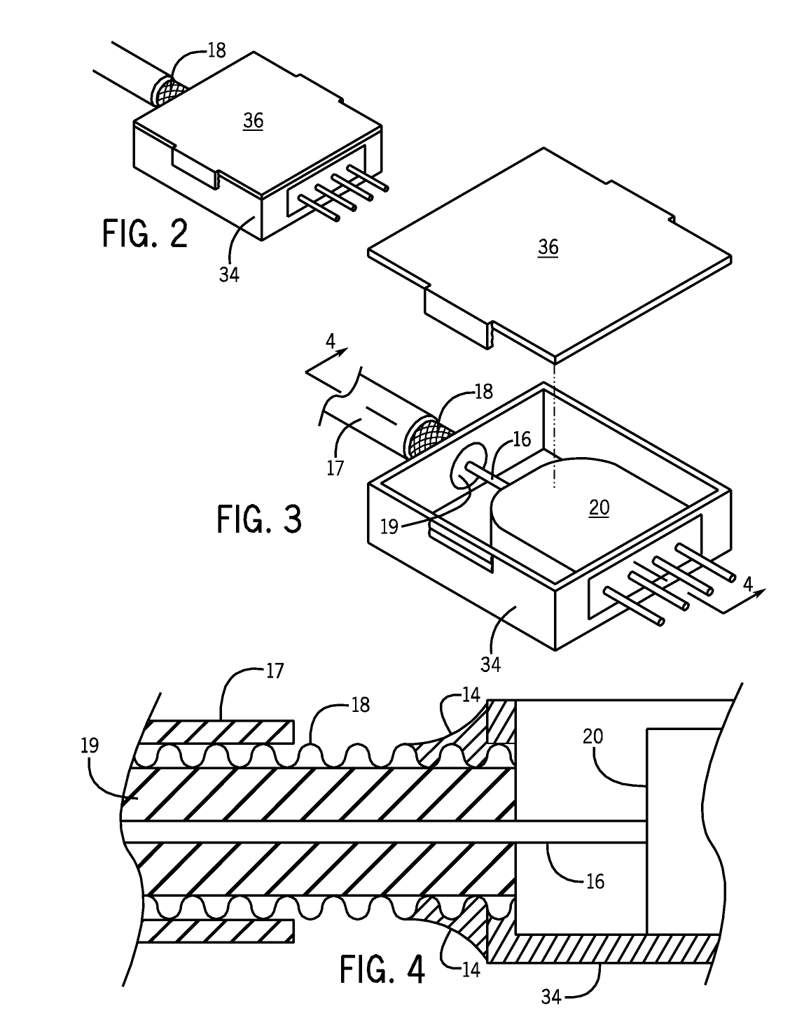

Referring now to FIGS. 2, 3, and 4, the mated connectors/bulkheads 20 may be shielded and enclosed by a connector case 34 and a connector lid 36 that may insulate and shield the mated connector/bulkheads 20. The busses 16 may be enclosed by bus insulation 19, conductive bus shields 18, and outer sheath insulation 17 until the busses 16 reach the connector case 34. The conductive bus shields 18 may be braised to the connector case 34 to form a solid and reliable electrical connection. The busses 16 may connect to the mated connectors/bulkheads 20 inside the connector case 34. A chassis ground connection 14 may allow the connector case 34 as well as the conductive bus shields 18 to be physically ground to the chassis.

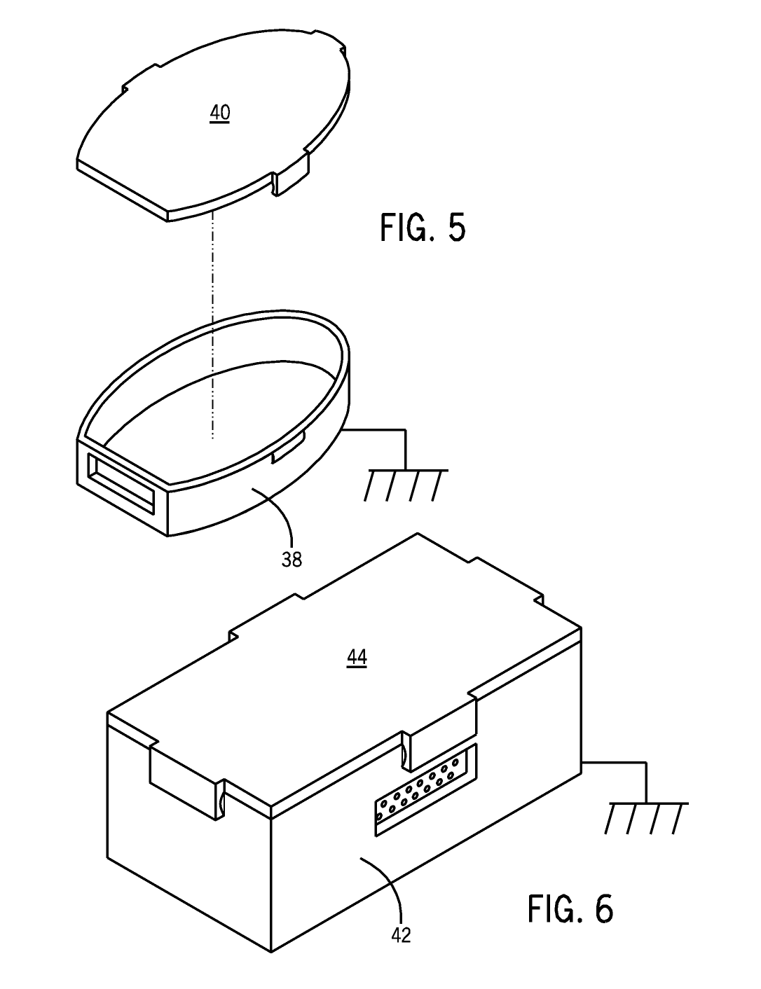

Referring now to FIG. 5, an actuator case 38 and an actuator lid 40 may enclose and shield actuators 30. The actuator case 38 may be custom formed for each type of actuators 30. Cables may not enter the actuator case 38 nor may cables connect directly to any actuators 30 inside the actuator case 38. Rather a cable may mate to an actuator case connector (not shown) and a separate internal wiring harness (not shown) may connect the case connector to the actuator 30.

Referring now to FIG. 6, a computer case 42 and a computer lid 44 may enclose and shield computers 26. The computer case 42 may be custom formed for each type of computers 26. Cables may not enter the computer case 42 nor may cables connect directly to any computers 26 inside the computer case 42. Rather a cable may mate to a computer case connector (not shown) and a separate internal wiring harness (not shown) may connect the case connector to the computer 26.

In addition to vehicular drive by wire systems, the shielding may also be used in any situation where computer-controlled remote units or control signals are transferred along extended distances that may make those signals susceptible to interference.

It should be understood, of course, that the foregoing relates to exemplary embodiments of the invention and that modifications may be made without departing from the spirit and scope of the invention as set forth in the following claims.

We claim:

1. A shielding system for protecting a drive by wire system, the shielding system comprising:
a conductive computer shield tied electrically to ground for enclosing computers within the drive by wire system; and
a conductive bus shield tied electrically to ground for enclosing busses that carry signals between the computers within the drive by wire system.

2. The shielding system of claim 1, further comprising:
a conductive connector shield tied electrically to ground for enclosing connectors that connect the computers to the busses within the drive by wire system.

3. The shielding system of claim 1, wherein the ground is chassis ground.

4. The shielding system of claim 1, further comprising:
a conductive connector shield for enclosing a connector within the drive by wire system, the conductive connector shield;

5. The shielding system of claim 1, further comprising:
a conductive actuator shield for enclosing an actuator within the drive by wire system, the conductive actuator shield including an actuator case connector to connect to a bus and an internal wiring harness to connect the actuator case connector to the actuator;

6. The shielding system of claim 1, wherein the conductive bus shield is a braised shield

7. A method for shielding a drive by wire system, the method comprising:
enclosing computers within the drive by wire system with a conductive computer shield;
enclosing busses that carry signals between the computers within the drive by wire system with a conductive bus shield;
tying the conductive computer shield to ground; and
tying the conductive bus shield to ground.

8. The method of claim 7, further comprising:
enclosing connectors that connect the computers to the busses within the drive by wire system with a conductive connectors shield; and
tying the conductive computer shield to ground.

9. The method of claim 7, further comprising:
enclosing actuators within the drive by wire system with a conductive actuator shield; and
enclosing connectors within the drive by wire system with a conductive connector shield.

10. The method of claim 7, wherein:
tying the conductive computer shield to ground includes tying the conductive computer shield to chassis ground; and
tying the conductive bus shield to ground includes tying the conductive bus shield to chassis ground.
